(19) United States
(12) Patent Application Publication
(10) Pub. No.: US 2025/0375798 A1
(43) Pub. Date: Dec. 11, 2025

(54) SUBSTRATE PROCESSING METHOD AND SUBSTRATE PROCESSING APPARATUS

(71) Applicant: SCREEN Holdings Co., Ltd., Kyoto (JP)

(72) Inventors: Keisuke MIYAJIMA, Kyoto (JP); Tomohiro TAKAHASHI, Kyoto (JP); Yasuhiko NAGAI, Kyoto (JP); Tadashi MAEGAWA, Kyoto (JP)

(21) Appl. No.: 19/234,983

(22) Filed: Jun. 11, 2025

(30) Foreign Application Priority Data
Jun. 11, 2024 (JP) 2024-094380

(51) Int. Cl. B08B 3/02; B08B 3/04; B08B 3/10; H01L 21/67

(52) U.S. Cl. CPC B08B 3/022; B08B 3/041; B08B 3/108; H01L 21/67051; H01L 21/6708

(57) ABSTRACT

A substrate processing method includes causing a first outer nozzle to discharge a processing liquid while causing a second outer nozzle to stop discharging a processing liquid, the first outer nozzle and the second outer nozzle arranged at positions higher than a position of the inner bath so as to be positioned opposite to each other with respect to a vertical line passing through a center of the substrate when viewed in a direction perpendicular to the substrate held on the lifter, and discharging the processing liquid toward the substrate held on the lifter, and causing the second outer nozzle to discharge the processing liquid while causing the first outer nozzle to stop discharging the processing liquid.

### CROSS REFERENCE TO RELATED APPLICATIONS

This application claims the benefit of priority to Japanese Patent Application No. 2024-094380 filed on Jun. 11, 2024. The entire contents of this application are hereby incorporated herein by reference.

### BACKGROUND OF THE INVENTION

### 1. Field of the Invention

The present invention relates to a substrate processing method and a substrate processing apparatus that process a substrate. The substrate includes a semiconductor wafer, a substrate for a FPD (Flat Panel Display) such as a liquid crystal display and an organic EL (electroluminescence) display, a substrate for an optical disc, a substrate for a magnetic disc, a substrate for a magneto-optical disc, a substrate for a photomask, a ceramic substrate, a substrate for a solar cell, and the like, for example.

### 2. Description of Related Art

JP 2010-225832 A discloses that two shower nozzles are arranged over a processing bath, and a processing liquid is discharged in a shower shape from the two shower nozzles toward a substrate within the processing bath.

In the substrate processing apparatus described in JP 2010-225832 A, since the shower nozzles discharge the processing liquid toward the substrate in a mutually opposing manner with respect to the lifter, the processing liquid discharged from one of the shower nozzles and the processing liquid discharged from the other shower nozzle collide with each other before reaching the substrate, and thus the kinetic energy of the processing liquid before colliding with the substrate decreases.

At least one preferred embodiment of the present invention provides a substrate processing method and a substrate processing apparatus that are capable of preventing a decrease in kinetic energy of a processing liquid before colliding with a substrate.

### SUMMARY OF THE INVENTION

A preferred embodiment of the present invention provides a substrate processing method including holding a substrate in an upright posture on a lifter movable vertically between an upper position where the substrate held on the lifter is arranged over an opening of an inner bath and a lower position where the substrate held on the lifter is arranged in a storage space of the inner bath, causing a first outer nozzle to discharge a processing liquid while causing a second outer nozzle to stop discharging a processing liquid, the first outer nozzle and the second outer nozzle arranged at positions higher than a position of the inner bath so as to be positioned opposite to each other with respect to a vertical line passing through a center of the substrate when viewed in a direction perpendicular to the substrate held on the lifter, and discharging the processing liquid toward the substrate held on the lifter, and causing the second outer nozzle to discharge the processing liquid, while causing the first outer nozzle to stop discharging the processing liquid.

In the preferred embodiment, at least one of the following features may be added to the substrate processing method.

The substrate processing method further includes vertically reciprocating the lifter within a range in which the processing liquid discharged from the first outer nozzle or the second outer nozzle continues to collide with the substrate in at least one of when causing the first outer nozzle to discharge the processing liquid while causing the second outer nozzle to stop discharging the processing liquid and when causing the second outer nozzle to discharge the processing liquid while causing the first outer nozzle to stop discharging the processing liquid.

The substrate processing method further includes draining the processing liquid inside the inner bath when causing the first outer nozzle to discharge the processing liquid while causing the second outer nozzle to stop discharging the processing liquid and when causing the second outer nozzle to discharge the processing liquid while causing the first outer nozzle to stop discharging the processing liquid.

The substrate processing method further includes causing both of the first outer nozzle and the second outer nozzle to discharge the processing liquid, while stopping draining of the processing liquid from the inner bath in a state where the lifter is arranged at the lower position after causing the first outer nozzle to discharge the processing liquid while causing the second outer nozzle to stop discharging the processing liquid and causing the second outer nozzle to discharge the processing liquid while causing the first outer nozzle to stop discharging the processing liquid.

The substrate processing method further includes causing a processing liquid nozzle to discharge the processing liquid when causing both of the first outer nozzle and the second outer nozzle to discharge the processing liquid while stopping draining of the processing liquid from the inner bath in a state where the lifter is arranged at the lower position, the processing liquid nozzle arranged at a position where at least a portion of the processing liquid nozzle is in contact with the processing liquid inside the inner bath and discharging the processing liquid toward the storage space of the inner bath.

Another preferred embodiment of the present 5 invention provides a substrate processing apparatus including an inner bath that forms an opening through which a substrate vertically passes and a storage space that stores the substrate that has passed downward through the opening, the inner bath storing in the storage space a processing liquid to be supplied to the substrate, a lifter that holds the substrate in an upright posture, an elevating/lowering actuator that vertically moves the lifter between an upper position where the substrate held on the lifter is arranged over the opening of the inner bath and a lower position where the substrate held on the lifter is arranged in the storage space of the inner bath, and a first outer nozzle and a second outer nozzle that are arranged at positions higher than a position of the inner bath so as to be positioned opposite to each other with respect to a vertical line passing through a center of the substrate when viewed in a direction perpendicular to the substrate held on the lifter, and that discharge the processing liquid toward the substrate held on the lifter, wherein the first outer nozzle and the second outer nozzle are caused to perform causing the first outer nozzle to discharge the processing liquid while causing the second outer nozzle to stop discharging the processing liquid, and causing the second outer nozzle to discharge the processing liquid while causing the first outer nozzle to stop discharging the processing liquid.

In the preferred embodiment, at least one of the following features may be added to the substrate processing apparatus.

The elevating/lowering actuator is caused to perform vertically reciprocating the lifter within a range in which the processing liquid discharged from the first outer nozzle or the second outer nozzle continues to collide with the substrate in at least one of when causing the first outer nozzle to discharge the processing liquid while causing the second outer nozzle to stop discharging the processing liquid and when causing the second outer nozzle to discharge the processing liquid while causing the first outer nozzle to stop discharging the processing liquid.

The substrate processing apparatus further includes a drain valve that is switched between an open state in which the processing liquid is drained from the inner bath and a closed state in which the processing liquid is stopped from being drained from the inner bath, wherein the drain valve is caused to perform draining the processing liquid inside the inner bath when causing the first outer nozzle to discharge the processing liquid while causing the second outer nozzle to stop discharging the processing liquid and when causing the second outer nozzle to discharge the processing liquid while causing the first outer nozzle to stop discharging the processing liquid.

The first outer nozzle and the second outer nozzle are caused to perform causing both of the first outer nozzle and the second outer nozzle to discharge the processing liquid in a state where the drain valve is in the closed state and the lifter is arranged at the lower position after causing the first outer nozzle to discharge the processing liquid while causing the second outer nozzle to stop discharging the processing liquid and causing the second outer nozzle to discharge the processing liquid while causing the first outer nozzle to stop discharging the processing liquid.

The substrate processing apparatus further includes a processing liquid nozzle that is arranged at a position where at least a portion of the processing liquid nozzle is in contact with the processing liquid inside the inner bath and that discharges the processing liquid toward the storage space of the inner bath, wherein the liquid processing nozzle is caused to perform causing the processing liquid nozzle to discharge the processing liquid when causing both of the first outer nozzle and the second outer nozzle to discharge the processing liquid in a state where the drain valve is in the closed state and the lifter is arranged at the lower position.

The substrate processing apparatus may include a plurality of valves that are each switched between an open state to cause the processing liquid to pass the valve downstream and a closed state to stop the processing liquid at the valve, and a controller that switches each of the plurality of nozzles between a discharge execution state to discharge the processing liquid and a discharge stop state to stop discharging the processing liquid by controlling the states of the plurality of valves. In this case, the controller controls the states of the plurality of valves to cause the first outer nozzle, the second outer nozzle, and the like to perform a plurality of steps such as the first one-side discharging step and the second one-side discharging step. The plurality of nozzles may include not only the first outer nozzle and the second outer nozzle but also a nozzle other than the first outer nozzle and the second outer nozzle such as a processing liquid nozzle.

### BRIEF DESCRIPTION OF THE DRAWINGS

FIG. 1 is a schematic plan view showing a layout of a batch type substrate processing apparatus according to a preferred embodiment of the present invention.

FIG. 2 is a schematic view showing a cross section of a liquid processing bath taken along a vertical plane perpendicular to the front-back direction.

FIG. 3 is a schematic view showing a cross section of the liquid processing bath taken along a vertical plane perpendicular to the left-right direction.

FIG. 4 is a block diagram showing an electrical arrangement of the substrate processing apparatus.

FIG. 5 is a flow chart to explain an example of processing of a substrate performed by the substrate processing apparatus.

FIG. 6A and FIG. 6B are schematic views to explain the example.

FIG. 6C, FIG. 6D and FIG. 6E are schematic views to explain the example.

FIG. 6F and FIG. 6G are schematic views to explain the example.

### DETAILED DESCRIPTION OF PREFERRED EMBODIMENTS

Preferred embodiments of the present invention will be explained in detail with reference to the accompanying drawings.

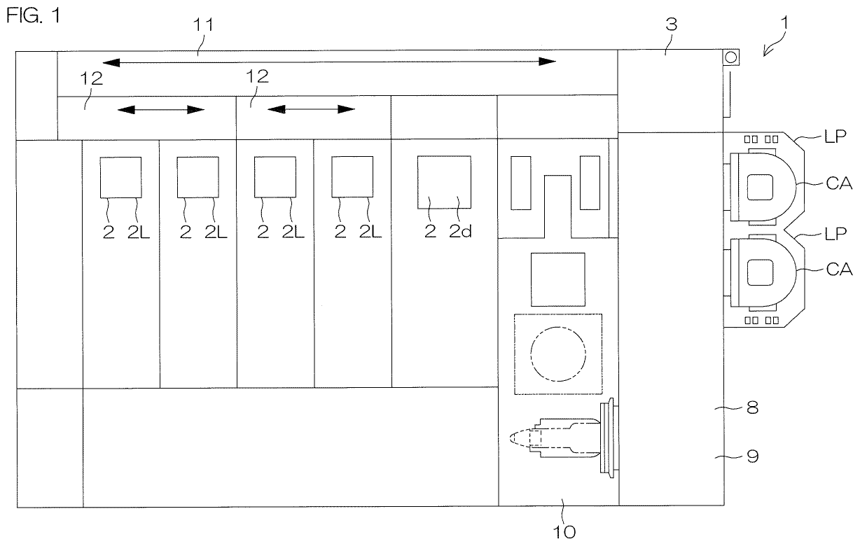

FIG. 1 is a schematic plan view showing a layout of a batch type substrate processing apparatus 1 according to a preferred embodiment of the present invention.

The substrate processing apparatus 1 is a batch type apparatus that processes a plurality of substrates W in a batch. The substrate processing apparatus 1 includes a load port LP that holds a carrier CA housing disk-shaped substrates W such as semiconductor wafers, a processing unit 2 that processes the substrate W transferred from the load port LP with a processing liquid such as a chemical liquid or a rinse liquid, a transfer system 8 that transfers the substrate W between the load port LP and the processing unit 2, and a controller 3 that controls the substrate processing apparatus 1.

The processing unit 2 includes a plurality of liquid processing baths 2L that each store a processing liquid in which a plurality of substrates W are immersed and a drying processing bath 2d that dries the plurality of substrates W by a drying method such as decompression drying. Decompression drying is a drying method in which a liquid adhering to the substrates W is evaporated by reducing air pressure. The plurality of pairs of liquid processing baths 2L are aligned rectilinearly in a depth direction (left-right direction of the sheet in FIG. 1) of the substrate processing apparatus 1 in a plan view. The drying processing bath 2d is arranged between a transfer system 8 and the plurality of liquid processing baths 2L in the depth direction of the substrate processing apparatus 1 in a plan view.

The plurality of liquid processing baths 2L may include a chemical liquid processing bath in which chemical liquid processing is performed for the plurality of substrates W and a rinse processing bath in which rinse processing is performed for the plurality of substrates W after the chemical liquid processing performed in the chemical liquid processing bath, or may include a multi-processing bath in which both of the chemical liquid processing and the rinse processing are performed. The plurality of liquid processing baths 2L may include the chemical liquid processing bath, the rinse processing bath, and the multi-processing bath. FIG. 1 shows an example in which all of the liquid processing baths 2L are multi-processing baths.

The transfer system 8 includes a carrier transfer apparatus 9 that transfers the carrier CA between the load port LP and the processing unit 2 and that houses a plurality of the carriers CA, and an orientation converting robot 10 that performs carry-in and carry-out of a plurality of substrates W with respect to the carrier CA held by the carrier transfer apparatus 9 and that changes orientations of the substrates W between a horizontal orientation and a vertical orientation. The orientation converting robot 10 performs a batching operation of forming a single batch with the plurality of substrates W taken out from the plurality of carriers CA and an unbatching operation of housing, in the plurality of carriers CA, the plurality of substrates W included in the single batch.

The transfer system 8 further includes a main transfer robot 11 that transfers the plurality of substrates W between the orientation converting robot 10 and the processing unit 2, and a plurality of auxiliary transfer robots 12 that transfer the plurality of substrates W between the main transfer robot 11 and the processing unit 2. FIG. 1 shows an example where two auxiliary transfer robots 12 and two pairs of liquid processing baths 2L are provided. The auxiliary transfer robot 12 performs carry-in and carry-out of the plurality of substrates W with respect to each of two processing units 2 in the pair and transfers the plurality of substrates W between the two processing units 2 in the pair.

The main transfer robot 11 receives the single batch of substrates W that is constituted of the plurality (for example, 50) of substrates W from the orientation converting robot 10 and transfers the received single batch of substrates W to one of the plurality of auxiliary transfer robots 12. The auxiliary transfer robot 12 immerses the single batch of substrates W received from the main transfer robot 11 into the processing liquid in at least one liquid processing bath 2L. Thereafter, the main transfer robot 11 receives the single batch of substrates W from the auxiliary transfer robot 12 and carries the received single batch of substrates W into the drying processing bath 2d.

Next, the liquid processing bath 2L shall be described.

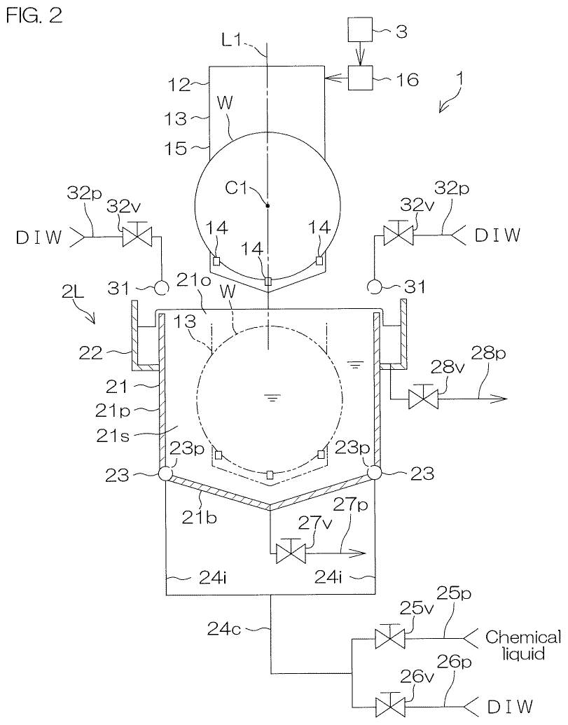

FIG. 2 is a schematic view showing a cross section of the liquid processing bath 2L taken along a vertical plane perpendicular to the front-back direction. FIG. 3 is a schematic view showing a cross section of the liquid processing bath 2L taken along a vertical plane perpendicular to the left-right direction. In FIG. 2, the direction perpendicular to the sheet corresponds to the direction perpendicular to the substrates W held on a lifter 13. FIG. 3 is a schematic view showing a cross section of the liquid processing bath 2L taken along a vertical plane perpendicular to the left-right direction and passing through a reference line L1. In FIG. 3, an outer bath 22 is not shown.

As shown in FIG. 2, the liquid processing bath 2L includes an inner bath 21 that stores the processing liquid. The inner bath 21 includes a cylindrical peripheral wall 21p extending vertically and a bottom wall 21b that closes the bottom of the peripheral wall 21p. The peripheral wall 21p forms an opening 210 through which the substrates W to be processed vertically pass, and a storage space 21s that stores the processing liquid to be supplied to the substrates W passing downward through the opening 210. The storage space 21s extends downward from the opening 210. The plurality of substrates W are placed inside the inner bath 21 and immersed in the processing liquid inside the inner bath 21. The liquid processing bath 2L may or may not include the outer bath 22 that stores the processing liquid overflowing from the inner bath 21. FIG. 2 shows an example of the former.

The auxiliary transfer robot 12 includes a lifter 13 that holds one or more substrates W in an upright posture and an elevating/lowering actuator 16 that vertically moves the lifter 13. The elevating/lowering actuator 16 stops the lifter 13 at an arbitrary position within a range from an upper position (a position indicated by the solid line in FIG. 2) to a lower position (a position indicated by the two-dot dash line in FIG. 2). The upper position is a position where the one or more substrates W held on the lifter 13 are entirely arranged over the opening 210 of the inner bath 21. The lower position is a position where the one or more substrates W held on the lifter 13 are entirely arranged inside the inner bath 21, that is, in the storage space 21s.

The actuator is a device that converts driving energy, which represents electrical, fluid, magnetic, thermal or chemical energy, to mechanical work. The actuator includes an electric motor (rotary motor), linear motor, air cylinder and other devices. If the motion of the actuator is different from the motion of the object, a motion converter may be provided to convert the motion of the actuator into linear motion or rotation. If the actuator is an electric motor and the object is to be moved in a linear motion, a motion converter, such as a ball screw and ball nut, may convert the rotation of the electric motor into linear motion.

The lifter 13 is an example substrate holder that holds the substrates W. The lifter 13 holds a plurality of substrates W such that the plurality of substrates W having the same shape and size face each other in parallel or substantially parallel at intervals in a horizontal front-back direction in an upright posture. The upright posture is a posture in which the substrates W are along a vertical plane. The lifter 13 may hold the plurality of substrates W in a vertical posture or may hold the plurality of substrates W in a posture inclined with respect to a vertical plane as long as the plurality of substrates W are parallel or substantially parallel. When the lifter 13 holds the plurality of substrates W, centers C1 of the plurality of substrates W are arranged along one straight line extending horizontally in the front-back direction.

The lifter 13 includes a plurality of support bars 14 that are arranged below the plurality of substrates W to be held, and a base plate 15 that is fixed to the plurality of support bars 14. FIG. 2 shows an example where three support bars 14 are provided. The plurality of support bars 14 extend horizontally from the base plate 15. Each support bar 14 has a plurality of grooves that receive the plurality of substrates W one by one. The plurality of substrates W are placed on the plurality of support bars 14 such that an outer peripheral portion of each substrate W is fitted into the groove of each support bar 14. This causes the substrates W to be inhibited from being inclined with respect to the plurality of support bars 14 and maintained in an upright posture.

The substrate processing apparatus 1 includes two processing liquid nozzles 23 that discharge the processing liquid inside the inner bath 21, two individual pipings 24i that guide the processing liquid toward the two processing liquid nozzles 23, and a common piping 24c that guides the processing liquid toward the two individual pipings 24i. The processing liquid flowing through the common piping 24c is supplied to the two processing liquid nozzles 23 through the two individual pipings 24i. Each processing liquid nozzle 23 discharges the processing liquid through a discharge port 23p that is arranged inside the inner bath 21 to supply the processing liquid into the inner bath 21 and forms an upflow of the processing liquid in the processing liquid inside the inner bath 21.

The substrate processing apparatus 1 includes a chemical liquid piping 25p that guides a chemical liquid toward the two processing liquid nozzles 23 and a chemical liquid valve 25v that is switched between an open state in which the chemical liquid flowing downstream within the chemical liquid piping 25p is allowed to pass therethrough and a closed state in which the chemical liquid is stopped. The substrate processing apparatus 1 further includes a rinse liquid piping 26p that guides a rinse liquid toward the two processing liquid nozzles 23 and a rinse liquid valve 26v that is switched between an open state in which the rinse liquid flowing downstream within the rinse liquid piping 26p is allowed to pass therethrough and a closed state in which the rinse liquid is stopped.

The chemical liquid piping 25p and the rinse liquid piping 26p are connected to the two processing liquid nozzles 23 through the common piping 24c and the two individual pipings 24i. When the chemical liquid valve 25v is opened, that is, when the chemical liquid valve 25v is switched from the closed state to the open state, the two processing liquid nozzles 23 discharge the chemical liquid. Similarly, when the rinse liquid valve 26v is opened, the two processing liquid nozzles 23 discharge the rinse liquid.

The chemical liquid may be a liquid that includes at least one of sulfuric acid, nitric acid, hydrochloric acid, hydrofluoric acid, phosphoric acid, acetic acid, ammonia water, hydrogen peroxide water, organic acids (for example, citric acid, oxalic acid, etc.), organic alkalis (for example, TMAH: tetramethylammonium hydroxide, etc.), surfactants, and corrosion inhibitors, or may be a liquid other than this. For example, the chemical liquid may be any one of SC1 (a mixture of ammonia water, hydrogen peroxide water, and water), SC2 (a mixture of hydrochloric acid, hydrogen peroxide water, and water), and SPM (a mixture of sulfuric acid and hydrogen peroxide water).

The rinse liquid may be any of pure water (DIW (Deionized Water)), carbonated water, electrolyzed ionized water, hydrogen water, ozone water, and hydrochloric acid solution having a dilution concentration (for example, about 10 to 100 ppm), or may be a liquid other than these. FIG. 2 shows an example where the rinse liquid is pure water.

Although not shown, the chemical liquid valve 25v includes a valve body provided with an annular valve seat through which a chemical liquid passes, a valve element that can move with respect to the valve seat, and an actuator that moves the valve element between a closed position where the valve element contacts the valve seat and an open position where the valve element is away from the valve seat. The same applies to other valves. The actuator may be a pneumatic actuator or an electric actuator, or may be an actuator other than these. The controller 3 opens and closes the chemical liquid valve 25v by controlling the actuator. The contents of this paragraph also apply to valves other than the chemical liquid valve 25v.

The substrate processing apparatus 1 includes a drain piping 27p that guides the processing liquid drained from the inner bath 21, and a drain valve 27v that is switched between an open state in which the processing liquid is drained from the inner bath 21 to the drain piping 27p and a closed state in which the processing liquid is stopped from being drained from the inner bath 21 to the drain piping 27p. The drain piping 27p is connected to a drain port that is opened at the bottom of an inner surface of the inner bath 21. If the liquid processing bath 2L includes the outer bath 22, the substrate processing apparatus 1 further includes a drain piping 28p that guides the processing liquid drained from the outer bath 22, and a drain valve 28v that is switched between an open state in which the processing liquid is drained from the outer bath 22 to the drain piping 28p and a closed state in which the processing liquid is stopped from being drained from the outer bath 22 to the drain piping 28p.

Next, an outer nozzle 31 that discharges the processing liquid over the inner bath 21 will be described.

As shown in FIG. 2, the substrate processing apparatus 1 includes two outer nozzles 31 that discharge the processing liquid toward the substrates W held on the lifter 13. The two outer nozzles 31 are arranged over the inner bath 21, that is, outside the inner bath 21. A vertical straight line passing through the center C1 of substrates W, when viewed in a direction perpendicular to the substrates W held on the lifter 13, is defined as a reference line L1. The two outer nozzles 31 are arranged opposite to each other with respect to the reference line L1. When the lifter 13 holds a plurality of substrates W and there is no processing liquid between the outer nozzles 31 and the substrates W, the processing liquid, even when it is discharged from any one of the outer nozzles 31, hits all of the substrates W held on the lifter 13.

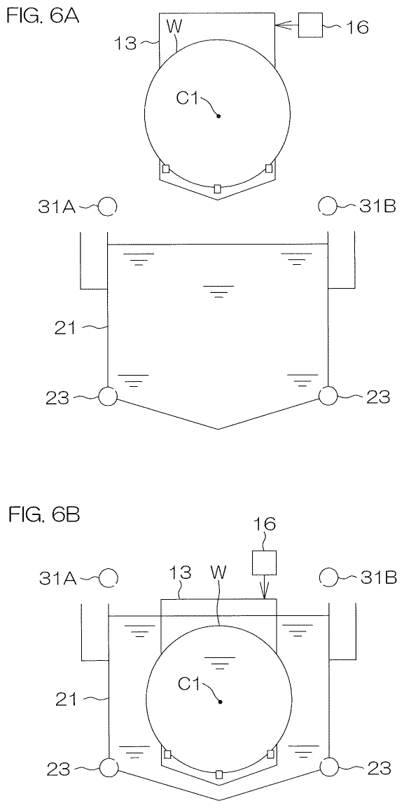

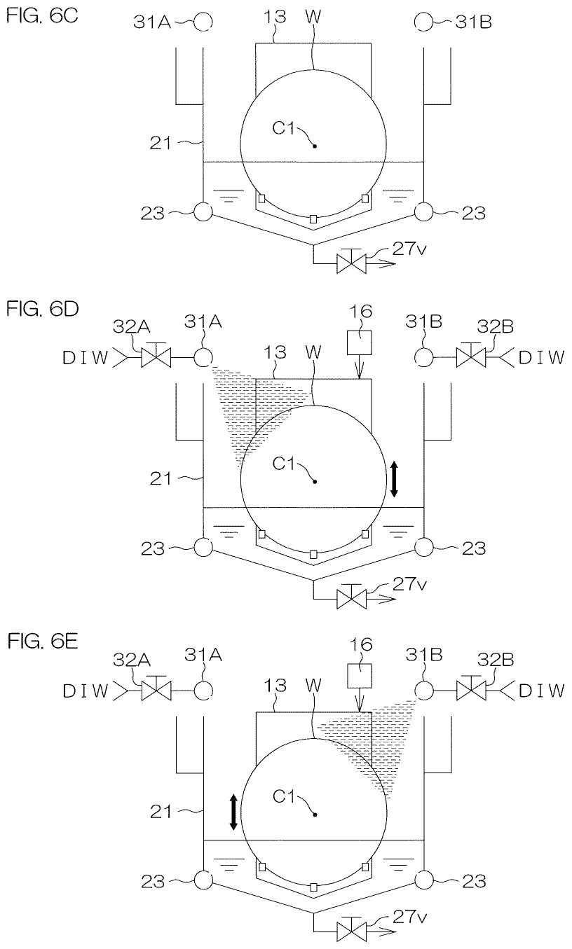

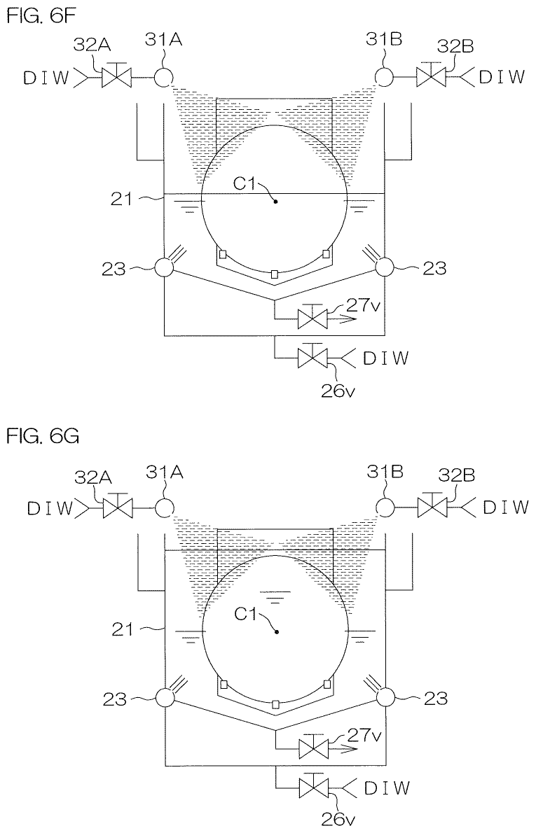

The two outer nozzles 31 are symmetrical with respect to the reference line L1. Accordingly, the two outer nozzles 31 are arranged at the same height, and the distance in the horizontal direction from the reference line L1 to each outer nozzle 31 is equal between the two outer nozzles 31. The two outer nozzles 31 have the same size. When one of the outer nozzles 31 is reversed with respect to the reference line L1, the shapes of the two outer nozzles 31 coincide with each other. The two outer nozzles 31 discharge the processing liquid downward. The directions in which the two outer nozzles 31 discharge the processing liquid are opposite to each other with respect to the reference line L1 (see FIG. 6F).

At least one of the height of each outer nozzle 31 and the distance in the horizontal direction from the reference line L1 to each outer nozzle 31 may be different between the two outer nozzles 31. The two outer nozzles 31 may have their respective different sizes. The shape of one of the outer nozzles 31 may be different from that of the other outer nozzle 31 when it is reversed with respect to the reference line L1. The directions in which the two outer nozzles 31 discharge the processing liquid may not be opposite to each other with respect to the reference line L1.

Each of the outer nozzles 31 includes a plurality of discharge ports that discharge the processing liquid toward the substrates W held on the lifter 13. In FIG. 3, a plurality of points drawn in the nozzle heads 31h indicate a plurality of discharge ports. Each of the discharge ports is arranged at a position higher than that of the inner bath 21. As described above, the lifter 13 holds the plurality of substrates W such that the plurality of substrates W are aligned in the front-back direction (left-right direction of the sheet in FIG. 3) in an upright posture. At least one discharge port is arranged at each of a plurality of discharge positions separated in the front-back direction. The outer nozzles 31 may discharge the processing liquid in a shower form or a mist form at each discharge position or may discharge the processing liquid in other forms. FIGS. 6D and 6E to be described below illustrate an example in which the outer nozzles 31 are shower nozzles that discharge the processing liquid such that the shower-formed processing liquid diffuses only within a space extending conically from one or more discharge ports at each discharge position.

Each of the outer nozzles 31 includes a linear nozzle tube 31t that guides the processing liquid to be discharged from the plurality of discharge ports. The nozzle tube 31t extends in the front-back direction. The plurality of discharge ports may be opened in an outer peripheral surface of the nozzle tube 31t or may be opened in an outer surface of the nozzle heads 31h that are attached to the nozzle tube 31t. FIG. 3 shows an example of the latter. In this example, the plurality of nozzle heads 31h, which are arranged one by one at a plurality of discharge positions, are attached to the nozzle tube 31t. The processing liquid within the nozzle tube 31t is supplied to each nozzle head 31h and discharged from a plurality of discharge ports of each nozzle head 31h.

As shown in FIG. 2, the substrate processing apparatus 1 includes two rinse liquid pipings 32p that guides the rinse liquid toward the two outer nozzles 31 and two rinse liquid valves 32v that are switched between an open state in which the rinse liquid flowing downstream within the rinse liquid pipings 32p is allowed to pass therethrough and a closed state in which the rinse liquid is stopped. The rinse liquid pipings 32p are an example of processing liquid pipings that guide the processing liquid toward the outer nozzles 31. The rinse liquid valves 32v are an example of processing liquid valves that are switched between an open state in which the processing liquid flowing downstream within the processing liquid piping is allowed to pass therethrough and a closed state in which the processing liquid is stopped.

When both of the rinse liquid valves 32v are opened, both of the outer nozzles 31 discharge the rinse liquid. When both of the rinse liquid valves 32v are closed, both of the outer nozzles 31 stop discharging the rinse liquid. When one of the rinse liquid valves 32v is opened, one of the outer nozzles 31 discharges the rinse liquid. When the other rinse liquid valve 32v is opened, the other outer nozzle 31 discharges the rinse liquid. Accordingly, the controller 3 can switch the number of outer nozzles 31 that are discharging the rinse liquid, which is an example of the processing liquid, by switching the states of the two rinse liquid valves 32v.

Next, an electrical arrangement of the substrate processing apparatus 1 will be described.

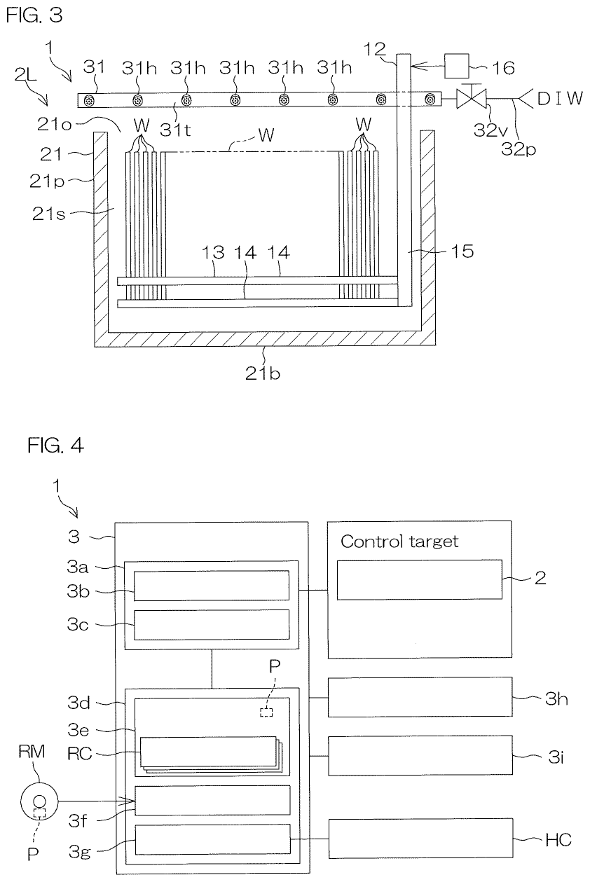

FIG. 4 is a block diagram showing the electrical arrangement of the substrate processing apparatus 1. The substrate processing apparatus 1 includes a controller 3 that controls electrical devices and electronic devices included in the substrate processing apparatus 1. The controller 3 includes at least one computer that can communicate with each other. The computer includes a computer main body 3a and a peripheral device 3d connected to the computer main body 3a.

The computer main body 3a includes a CPU 3b (central processing unit) that executes various types of commands and a memory 3c that stores information to be sent to and received from the CPU 3b. The peripheral device 3d includes a storage 3e that stores information to be sent to and received from the memory 3c such as a program P, a reader 3f that reads information from a removable medium RM, and a communication device 3g that communicates with other devices such as a host computer HC. The memory 3c and the storage 3e are both examples of a memory that stores information to be sent to and received from the CPU 3b.

The controller 3 is connected to an input device 3h and a display 3i. The input device 3h is operated when an operator such as a user or a maintenance operator inputs information to the substrate processing apparatus 1. The information is displayed on the screen of the display 3i. The input device 3h may be any of a keyboard, a pointing device and a touch panel or may be a device other than these. A touch panel display that serves both as the input device 3h and the display 3i may be provided in the substrate processing apparatus 1.

The CPU 3b executes the program P stored in the storage 3e. The program P within the storage 3e may be previously installed in the controller 3, may be fed through the reader 3f from the removable medium RM to the storage 3e or may be fed from an external device such as the host computer to the storage 3e through the communication device 3g.

The memory 3c is a volatile memory that retains memory only when power is supplied. The storage 3e and the removable medium RM are non-volatile memories that retain memory even when power is not supplied. The storage 3e is, for example, a magnetic storage device such as a hard disk drive. The removable medium RM is, for example, an optical disc such as a compact disc or a semiconductor memory such as a memory card. The removable medium RM is an example of a computer readable recording medium in which the program P is recorded. The removable medium RM is a non-transitory tangible recording medium (non-transitory tangible media).

The storage 3e stores a plurality of recipes RC. The recipe RC is information that specifies the details of processing, processing conditions and processing procedures of the substrate W. A plurality of recipes RC differ from each other in at least one of the details of processing, the processing conditions and the processing procedures of the substrate W. The controller 3 controls the substrate processing apparatus 1 such that the substrate W is processed according to the recipe RC designated by the host computer HC. The controller 3 is programmed to execute the individual steps described below. The program P to execute the individual steps described below may be stored in either the storage 3e or the removable medium RM.

Next, an example of processing of the substrate W performed by the substrate processing apparatus 1 will be described.

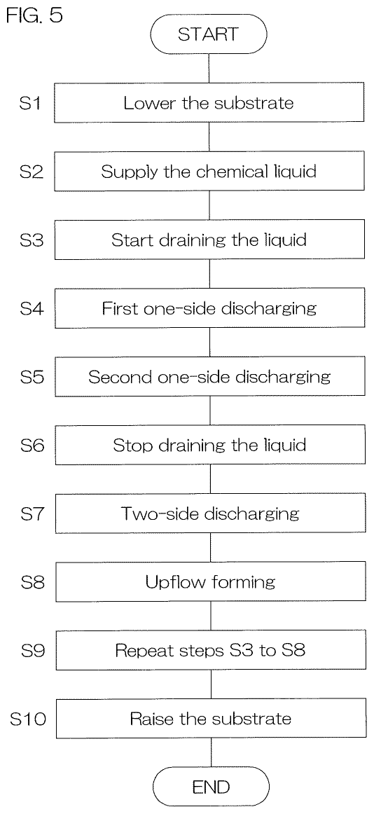

FIG. 5 is a flow chart to explain the example. FIG. 6A, FIG. 6B, FIG. 6C, FIG. 6D, FIG. 6E, FIG. 6F, and FIG. 6G are schematic views to explain the example. Hereinafter, one of the outer nozzles 31 may be referred to as a first outer nozzle 31A, and the other outer nozzle 31 may be referred to as a second outer nozzle 31B. The rinse liquid valve 32v corresponding to the first outer nozzle 31A may be referred to as a first rinse liquid valve 32A, and the rinse liquid valve 32v corresponding to the second outer nozzle 31B may be referred to as a second rinse liquid valve 32B.

When a substrate W is processed in the substrate processing apparatus 1, as shown in FIGS. 6A and 6B, at least one substrate W is held on the lifter 13, and the elevating/lowering actuator 16 moves the lifter 13 from the upper position to the lower position with the chemical liquid stored in the inner bath 21 (step S1 in FIG. 5). When the lifter 13 is arranged at the lower position, all of the substrates W held on the lifter 13 move into the inner bath 21 and arranged at a position lower than that of the surface of the chemical liquid inside the inner bath 21. This causes a chemical liquid supplying step (step S2 in FIG. 5) to be performed in which the chemical liquid is supplied to the entire region of the front surface and the rear surface of each substrate W.

When a predetermined time elapses after the lifter 13 is arranged at the lower position, a draining step (step S3 in FIG. 5) is started in which the processing liquid inside the inner bath 21 is drained in a state where the lifter 13 is located at the lower position. Specifically, the drain valve 27v is opened to start draining the processing liquid inside the inner bath 21. As a result, the chemical liquid inside the inner bath 21 decreases, and the surface (upper surface) of the chemical liquid inside the inner bath 21 starts to descend. When a predetermined time elapses after the chemical liquid starts to be drained, as illustrated in FIG. 6C, the surface of the chemical liquid inside the inner bath 21 descends to a position between the upper end of the substrates W and the lower end of the substrates W, and the substrates W are partially exposed from the chemical liquid inside the inner bath 21.

After the substrates W are partially exposed from the chemical liquid inside the inner bath 21, as illustrated in FIG. 6D, a first one-side discharging step (step S4 in FIG. 5) is performed in which the first outer nozzle 31A is caused to discharge pure water, while the second outer nozzle 31B is caused to stop discharging pure water. Specifically, in a state where the drain valve 27v is opened and the second rinse liquid valve 32B is closed, the first rinse liquid valve 32A is opened to cause the first outer nozzle 31A to start discharging pure water. A portion of the pure water discharged from the first outer nozzle 31A collides with all of the substrates W held on the lifter 13 that is located at the lower position, and then stored in the inner bath 21. The remaining pure water is stored in the inner bath 21 without colliding with the substrates W. The flow rate of the pure water supplied from the first outer nozzle 31A to the inner bath 21 is smaller than the flow rate of the processing liquid drained from the inner bath 21. Accordingly, the processing liquid inside the inner bath 21 continues to decrease even while the first outer nozzle 31A discharges pure water.

When a predetermined time elapses after the first outer nozzle 31A starts discharging pure water, as shown in FIG. 6E, a second one-side discharging step (step S5 in FIG. 5) is performed in which the second outer nozzle 31B is caused to discharge pure water, while the first outer nozzle 31A is caused to stop discharging pure water. Specifically, the first rinse liquid valve 32A is closed, and the first outer nozzle 31 A is caused to stop discharging pure water. Concurrently or thereafter, in a state where the drain valve 27v is open, the second rinse liquid valve 32B is opened to cause the second outer nozzle 31B to start discharging pure water. A portion of the pure water discharged from the second outer nozzle 31B collides with all of the substrates W held on the lifter 13 that is located at the lower position, and then stored in the inner bath 21. The remaining pure water is stored in the inner bath 21 without colliding with the substrates W. The flow rate of the pure water supplied from the second outer nozzle 31B to the inner bath 21 is smaller than the flow rate of the pure water drained from the inner bath 21.

When the second outer nozzle 31B is discharging pure water, the elevating/lowering actuator 16 may perform a reciprocating step of vertically reciprocating the lifter 13 within a range in which the pure water discharged from the second outer nozzle 31B continues to collide with the substrate W, or may perform a stationary step of keeping the lifter 13 still at the lower position. The same applies when the first outer nozzle 31A is discharging pure water. The thick arrows illustrated in FIGS. 6D and 6E indicate that the lifter 13 is vertically reciprocated. The reciprocating step may be performed when one of the first outer nozzle 31A and the second outer nozzle 31B is discharging pure water, and the stationary step may be performed when the other of the first outer nozzle 31A and the second outer nozzle 31B discharges pure water.

The flow rate of the pure water discharged from the second outer nozzle 31B may be equal to, or larger or smaller than the flow rate of the pure water discharged from the first outer nozzle 31A. The time during which the first outer nozzle 31A discharges pure water and the second outer nozzle 31B stops discharging pure water may be equal to, or longer or shorter than the time during which the second outer nozzle 31B discharges pure water and the first outer nozzle 31 A stops discharging pure water.

Thus, when one of the first outer nozzle 31A and the second outer nozzle 31B is discharging pure water, the other of the first outer nozzle 31A and the second outer nozzle 31B stops discharging pure water. It is therefore possible to prevent the pure water discharged from the first outer nozzle 31A and the pure water discharged from the second outer nozzle 31B from weakening each other in force. Further, most of the pure water discharged from the second outer nozzle 31B and colliding with the substrate W collides with the substrate W at a position different from that where the pure water discharged from the first outer nozzle 31A collides with the substrate W. This allows pure water to directly collide with a wider region within the front surface and the rear surface of each substrate W.

When a predetermined time elapses after the second outer nozzle 31B starts discharging pure water, in a state where the second rinse liquid valve 32B is open, the drain valve 27v is closed (step S6 in FIG. 5) and the first rinse liquid valve 32A is opened (step S7 in FIG. 5). Further, the rinse liquid valve 26v is opened (step S8 in FIG. 5), and the two processing liquid nozzles 23 are caused to start discharging pure water.

When the drain valve 27v is closed, the draining step is thereby terminated. When the rinse liquid valve 26v is opened, an upflow forming step of storing the processing liquid in the inner bath 21 is thereby started. The first rinse liquid valve 32A may be opened simultaneously with closing of the drain valve 27v, or may be opened before or after closing of the drain valve 27v. The same applies to the rinse liquid valve 26v. The rinse liquid valve 26v may be opened simultaneously with the opening of the first rinse liquid valve 32A, or may be opened before or after the opening of the first rinse liquid valve 32A.

Since the second rinse liquid valve 32B is open, when the first rinse liquid valve 32A is opened, as shown in FIG. 6F, both of the first outer nozzle 31A and the second outer nozzle 31B discharge pure water. The two-side discharging step is thereby started. When the first outer nozzle 31A and the second outer nozzle 31B discharge pure water with the drain valve 27v closed, the pure water is stored in the inner bath 21. In this state, the pure water discharged from the two processing liquid nozzles 23 is also stored in the inner bath 21. Accordingly, the pure water inside the inner bath 21 increases at a higher rate than when only the first outer nozzle 31A and the second outer nozzle 31B discharge the pure water.

As shown in FIG. 6G, the surface of the pure water inside the inner bath 21 moves upward as the pure water inside the inner bath 21 increases. When the surface of the pure water inside the inner bath 21 reaches a position above the upper end of the substrate W held on the lifter 13 that is located at the lower position, the first rinse liquid valve 32A, the second rinse liquid valve 32B, and the rinse liquid valve 26v are closed. These valves may be closed simultaneously or non-simultaneously. Two of the first rinse liquid valve 32A, the second rinse liquid valve 32B, and the rinse liquid valve 26v may be closed simultaneously, and the remaining one may be closed at another time.

After the first outer nozzle 31A, the second outer nozzle 31B, and the processing liquid nozzles 23 stop discharging the pure water, the first outer nozzle 31 A and the second outer nozzle 31B are caused to alternately discharge pure water, while draining the pure water inside the inner bath 21 again, and then the pure water is stored in the inner bath 21 until the surface of the pure water reaches a position above the upper end of the substrate W. That is, a repeating step (step S9 in FIG. 5) is performed in which one cycle from the draining step (step S3 in FIG. 5) to the upflow forming step (step S8 in FIG. 5) is performed. The cycle is thus performed twice. The steps from the draining step (step S3 in FIG. 5) to the repeating step (step S9 in FIG. 5) correspond to a rinse liquid supplying step of supplying pure water, which is an example of a rinse liquid, to the substrate W.

After the final upflow forming step (step S8 in FIG. 5) is performed, at least one substrate W is held on the lifter 13, and the elevating/lowering actuator 16 moves the lifter 13 from the lower position to the upper position with the pure water stored in the inner bath 21 (step S10 in FIG. 5). As a result, all of the substrates W held on the lifter 13 are separated upward away from the surface of the pure water inside the inner bath 21 and move to the outside of the inner bath 21. The substrates W held on the lifter 13 are then transferred to the drying processing bath 2d and dried in the drying processing bath 2d (see FIG. 1).

Next, the advantages according to the preferred embodiment will be described.

In this preferred embodiment, while the second outer nozzle 31B stops discharging the processing liquid, the first outer nozzle 31A discharges the processing liquid toward the substrates W held on the lifter 13. Thereafter, while the first outer nozzle 31A stops discharging the processing liquid, the second outer nozzle 31B discharges the processing liquid toward the substrates W held on the lifter 13. It is therefore possible to prevent the processing liquid discharged from the first outer nozzle 31A and the processing liquid discharged from the second outer nozzle 31B from colliding with each other before reaching the substrates W and thereby to prevent a decrease in the kinetic energy of the processing liquid before colliding with the substrates W. Furthermore, if the total time of discharging the processing liquid toward the substrates W is the same, the consumption of the processing liquid can be reduced as compared with the case where the processing liquid is discharged from both of the first outer nozzle 31A and the second outer nozzle 31B.

In this preferred embodiment, while one of the first outer nozzle 31A and the second outer nozzle 31B stops discharging the processing liquid, the other of the first outer nozzle 31A and the second outer nozzle 31B discharges the processing liquid toward the substrates W held on the lifter 13 with the lifter 13 reciprocated vertically. The lifter 13 is reciprocated between an turn-back position and a lower turn-back position. When the lifter 13 is located at any position within this range, the processing liquid discharged from the first outer nozzle 31A or the second outer nozzle 31B directly collides with the substrates W. It is therefore possible to widen the range in which the processing liquid directly hits the substrates W, and to cause the processing liquid to directly collide with a wider region within the front surface and the rear surface of each substrate W.

In this preferred embodiment, the processing liquid inside the inner bath 21 is drained regardless of whether the first one-side discharging step or the second one-side discharging step is being performed. When a rinse liquid is discharged toward the substrates W to which the chemical liquid adheres, the chemical liquid is mixed with the rinse liquid colliding with the substrates W. Foreign substances such as particles may be included in the processing liquid colliding with the substrates W. By draining the processing liquid inside the inner bath 21, it is possible to drain processing liquid containing impurities, that is, a liquid or a solid different from the processing liquid discharged from the first outer nozzle 31A or the second outer nozzle 31B, from the inner bath 21, and thus such a processing liquid is unlikely to re-adhere to the substrates W.

In this preferred embodiment, after the first one-side discharging step and the second one-side discharging step, both of the first outer nozzle 31A and the second outer nozzle 31B discharge the processing liquid, while stopping draining of the processing liquid from the inner bath 21. Since the drainage of the processing liquid from the inner bath 21 is stopped, the processing liquid is stored in the inner bath 21. Furthermore, since both of the first outer nozzle 31A and the second outer nozzle 31B discharge the processing liquid, the processing liquid inside the inner bath 21 increases at a higher rate than when one of the first outer nozzle 31A and the second outer nozzle 31B stops discharging the processing liquid.

When the first outer nozzle 31A and the second outer nozzle 31B are discharging the processing liquid, the lifter 13 is arranged at the lower position, and the substrates W are arranged in the storage space 21s of the inner bath 21. It is therefore possible to cause the processing liquid discharged from the first outer nozzle 31A and the second outer nozzle 31B to collide with the substrates W, as well as to bring the processing liquid stored in the inner bath 21 into contact with the substrates W. Furthermore, after the first outer nozzle 31A or the second outer nozzle 31B discharges the processing liquid while draining the processing liquid inside the inner bath 21, the processing liquid is stored in the inner bath 21, whereby the substrates W can be arranged at least partially in the processing liquid having no or few impurities. This allows the substrates W to be processed efficiently with the processing liquid.

In this preferred embodiment, while the drainage of the processing liquid from the inner bath 21 is stopped, not only are the first outer nozzle 31A and the second outer nozzle 31B caused to discharge the processing liquid, but also the processing liquid nozzles 23 arranged at positions where at least a portion thereof is in contact with the processing liquid inside the inner bath 21 are caused to discharge the processing liquid. Accordingly, the processing liquid inside the inner bath 21 increases at a higher rate than when only the first outer nozzle 31A and the second outer nozzle 31B discharge the processing liquid. As a result, the time required to store the processing liquid in the inner bath 21 can be shortened, and the time required to process the substrates W can thus be shortened.

Next, other preferred embodiments will be described.

One or both of the two outer nozzles 31 may discharge the processing liquid not only when the lifter 13 is arranged at the lower position but also when the lifter 13 is arranged at a position other than the lower position. Alternatively, one or both of the two outer nozzles 31 may discharge the processing liquid only when the lifter 13 is arranged at a position other than the lower position.

In the processing of the substrates W shown in FIG. 5, if the substrates W can be sufficiently processed by the first cycle from the draining step (step S3 in FIG. 5) to the upflow forming step (step S8 in FIG. 5), the second cycle may not be performed. Alternatively, the third and subsequent cycles may be performed.

The drainage of the processing liquid inside the inner bath 21 may be stopped regardless of whether the first one-side discharging step (step S4 in FIG. 5) or the second one-side discharging step (step S5 in FIG. 5) is being performed. That is, one of the two outer nozzles 31 may be caused to discharge the processing liquid while the drainage of the processing liquid inside the inner bath 21 is stopped. In the processing of the substrates W shown in FIG. 5, the draining step may be stopped at the same time as or before the start of the first one-side discharging step.

After the first one-side discharging step and the second one-side discharging step, both of the processing liquid nozzles 31 may be caused to discharge the processing liquid while both of the outer nozzles 23 are caused to stop discharging the processing liquid to store the processing liquid inside the inner bath 21 with the lifter 13 located at the lower position.

After the first one-side discharging step and before the second one-side discharging step, both of the outer nozzles 31 may be caused to stop discharging the processing liquid. In this case, the time during which both of the outer nozzles 31 discharge the processing liquid is preferably shorter than the time during which one of the outer nozzles 31 (the first outer nozzle 31A or the second outer nozzle 31B) discharges the processing liquid. This is because the consumption of the processing liquid can be reduced.

Two or more arrangements among all the arrangements described above may be combined. Two or more steps among all the steps described above may be combined.

The preferred embodiments of the present invention are described in detail above, however, these are just detailed examples used for clarifying the technical contents of the present invention, and the present invention should not be limitedly interpreted to these detailed examples, and the spirit and scope of the present invention should be limited only by the claims appended hereto.

What is claimed is:

1. A substrate processing method comprising:
holding a substrate in an upright posture on a lifter movable vertically between an upper position where the substrate held on the lifter is arranged over an opening of an inner bath and a lower position where the substrate held on the lifter is arranged in a storage space of the inner bath;
causing a first outer nozzle to discharge a processing liquid while causing a second outer nozzle to stop discharging a processing liquid, the first outer nozzle and the second outer nozzle arranged at positions higher than a position of the inner bath so as to be positioned opposite to each other with respect to a vertical line passing through a center of the substrate when viewed in a direction perpendicular to the substrate held on the lifter, and discharging the processing liquid toward the substrate held on the lifter; and
causing the second outer nozzle to discharge the processing liquid while causing the first outer nozzle to stop discharging the processing liquid.

2. The substrate processing method according to claim 1, further comprising vertically reciprocating the lifter within a range in which the processing liquid discharged from the first outer nozzle or the second outer nozzle continues to collide with the substrate in at least one of when causing the first outer nozzle to discharge the processing liquid while causing the second outer nozzle to stop discharging the processing liquid and when causing the second outer nozzle to discharge the processing liquid while causing the first outer nozzle to stop discharging the processing liquid.

3. The substrate processing method according to claim 1, further comprising draining the processing liquid inside the inner bath when causing the first outer nozzle to discharge the processing liquid while causing the second outer nozzle to stop discharging the processing liquid and when causing the second outer nozzle to discharge the processing liquid while causing the first outer nozzle to stop discharging the processing liquid.

4. The substrate processing method according to claim 3, further comprising causing both of the first outer nozzle and the second outer nozzle to discharge the processing liquid while stopping draining of the processing liquid from the inner bath in a state where the lifter is arranged at the lower position after causing the first outer nozzle to discharge the processing liquid while causing the second outer nozzle to stop discharging the processing liquid and causing the second outer nozzle to discharge the processing liquid while causing the first outer nozzle to stop discharging the processing liquid.

5. The substrate processing method according to claim 4, further comprising causing a processing liquid nozzle to discharge the processing liquid when causing both of the first outer nozzle and the second outer nozzle to discharge the processing liquid while stopping draining of the processing liquid from the inner bath in a state where the lifter is arranged at the lower position, the processing liquid nozzle arranged at a position where at least a portion of the processing liquid nozzle is in contact with the processing liquid inside the inner bath and discharging the processing liquid toward the storage space of the inner bath.

6. A substrate processing apparatus comprising:
an inner bath that forms an opening through which a substrate vertically passes and a storage space that stores the substrate that has passed downward through the opening, the inner bath storing in the storage space a processing liquid to be supplied to the substrate;
a lifter that holds the substrate in an upright posture;
an elevating/lowering actuator that vertically moves the lifter between an upper position where the substrate held on the lifter is arranged over the opening of the inner bath and a lower position where the substrate held on the lifter is arranged in the storage space of the inner bath; and
a first outer nozzle and a second outer nozzle that are arranged at positions higher than a position of the inner bath so as to be positioned opposite to each other with respect to a vertical line passing through a center of the substrate when viewed in a direction perpendicular to the substrate held on the lifter, and that discharge the processing liquid toward the substrate held on the lifter, wherein
the first outer nozzle and the second outer nozzle are caused to perform causing the first outer nozzle to discharge the processing liquid while causing the second outer nozzle to stop discharging the processing liquid, and causing the second outer nozzle to discharge the processing liquid while causing the first outer nozzle to stop discharging the processing liquid.

7. The substrate processing apparatus according to claim 6, wherein the elevating/lowering actuator vertically reciprocates the lifter within a range in which the processing liquid discharged from the first outer nozzle or the second outer nozzle continues to collide with the substrate in at least one of when causing the first outer nozzle to discharge the processing liquid while causing the second outer nozzle to stop discharging the processing liquid and when causing the second outer nozzle to discharge the processing liquid while causing the first outer nozzle to stop discharging the processing liquid.

8. The substrate processing apparatus according to claim 6, further comprising a drain valve that is switched between an open state in which the processing liquid is drained from the inner bath and a closed state in which the processing liquid is stopped from being drained from the inner bath, wherein
the drain valve is caused to perform draining the processing liquid inside the inner bath when causing the first outer nozzle to discharge the processing liquid while causing the second outer nozzle to stop discharging the processing liquid and when causing the second outer nozzle to discharge the processing liquid while causing the first outer nozzle to stop discharging the processing liquid.

9. The substrate processing apparatus according to claim 8, wherein the first outer nozzle and the second outer nozzle are caused to perform causing both of the first outer nozzle and the second outer nozzle to discharge the processing liquid in a state where the drain valve is in the closed state and the lifter is arranged at the lower position after causing the first outer nozzle to discharge the processing liquid while causing the second outer nozzle to stop discharging the processing liquid and causing the second outer nozzle to discharge the processing liquid while causing the first outer nozzle to stop discharging the processing liquid.

10. The substrate processing apparatus according to claim 9, further comprising a processing liquid nozzle that is arranged at a position where at least a portion of the processing liquid nozzle is in contact with the processing liquid inside the inner bath and that discharges the processing liquid toward the storage space of the inner bath, wherein
the liquid processing nozzle is caused to perform causing the processing liquid nozzle to discharge the processing liquid when causing both of the first outer nozzle and the second outer nozzle to discharge the processing liquid in a state where the drain valve is in the closed state and the lifter is arranged at the lower position.
